(19) United States
(12) Patent Application Publication
(10) Pub. No.: US 2026/0088776 A1
(43) Pub. Date: Mar. 26, 2026

(54) TRANSFORMER WITH STACKED RESONATORS

(71) Applicant: Apple Inc., Cupertino, CA (US)

(72) Inventors: Chenhui NIU, San Diego, CA (US); Milad DARVISHI, San Diego, CA (US); Zhengan YANG, Del Mar, CA (US)

(21) Appl. No.: 18/892,834

(22) Filed: Sep. 23, 2024

(51) Int. Cl. H03F 1/56; H01F 27/28; H03F 3/195

(52) U.S. Cl. CPC H03F 1/565; H01F 27/28; H03F 3/195

(57) ABSTRACT

A stacked resonator circuit that includes a transformer and multiple resonator circuits is disclosed. The transformer circuit may include a primary coil and secondary coil and may receive an input signal from a particular circuit. The multiple resonator circuit, which are coupled to the transformer, may attenuate one or more frequency components included in the input signal to generate a filtered version of the input signal. The transformer circuit can relay the filtered version of the input signal to a different circuit.

### FIELD

This disclosure relates to filtering signals in computer systems and, more particularly, to using resonator circuits to attenuate particular frequency components in high-frequency signals.

### BACKGROUND

Modern computer systems include multiple circuit blocks designed to perform various functions. For example, such circuit blocks may include processors or processor cores configured to execute software or program instructions. Additionally, the circuit blocks may include memory circuits, mixed-signal or analog circuits, and the like.

Some computer systems also include radio-frequency (RF) circuits that allow such computer systems to connect to wireless networks. For example, such RF circuits may be configured to receive signals from a WiFi network, a cellular data network, and the like.

RF circuits included in computer system may perform various functions, such as amplification, down conversion of a RF signal to an intermediate-frequency (IF) signal, and the like. Such RF circuits may employ a variety of both active circuit components, e.g., transistors, as well as passive circuit elements, e.g., resistors, capacitors, inductors, transformers, etc.

### BRIEF DESCRIPTION OF THE DRAWINGS

FIG. 1 is a block diagram depicting an embodiment of a radio-frequency circuit that includes a stacked coupled resonator.

FIG. 2 is a block diagram depicting an embodiment of a transformer.

FIG. 3 is a block diagram depicting an embodiment of a particular resonator for use with a transformer.

FIG. 4 is a diagram depicting a topology of the particular resonator.

FIG. 5 is a block diagram depicting an embodiment of a different resonator for use with a transformer.

FIG. 6 is a diagram depicting a topology of the different resonator.

FIG. 7 is a diagram depicting a cross-section of a stacked coupled resonator.

FIG. 8 is a flow diagram depicting an embodiment of a method for operating a transformer with associated resonators.

FIG. 9 is a block diagram of an embodiment of a device that may include circuits that employ a stacked coupled resonator.

FIG. 10 is a block diagram of various embodiments of computer systems that may include a stacked coupled resonator.

FIG. 11 illustrates an example of a non-transitory computer-readable storage medium that stores circuit design information.

### DETAILED DESCRIPTION

Computer systems that connect to wireless networks, include radio-frequency circuits that receive electromagnetic waves associated such wireless networks and generate a signal that can be sampled for digital processing. Such radio-frequency circuits include antennas, amplifier circuits, mixer circuits, power detector circuits, and the like. In some cases, a transformer may be employed to couple different circuits together in a radio-frequency front-end circuit.

Mixer circuits can be employed in radio-frequency front-end circuits to down convert the frequency of a received electromagnetic signal. To down convert the frequency, a mixer circuit can mix a lower frequency signal with a received high-frequency signal. In some cases, the mixing operation includes switching transistors on and off which can result in a common-mode spur in the resultant intermediate-frequency signal.

In some radio-frequency front-end circuits, a power detector circuit is coupled to a mixer circuit by a transformer. The power detector circuit can be used as part of automatic gain control or in the detection of jamming signals. Such power detector circuits cannot distinguish between common-mode and differential signals at different frequencies, which can be problematic due to the common-mode spur introduced by the mixer circuit.

In some cases, an inductor and variable capacitor can be introduced into the center tap of the transformer circuit to attenuate undesirable portions of the intermediate-frequency signal. In some applications, the attenuation range can be large necessitating a large range of values for the capacitor. In some circuits, the variable capacitor can be implemented as a bank of metal-oxide-metal capacitors. Such capacitors are prone to manufacturing variation and tuning a bank of such capacitors are high frequencies can be problematic.

The embodiments illustrated in the drawings and described below provide techniques for attenuating undesired frequencies in a radio-frequency circuit. By employing stacked resonator circuits coupled to a transformer that couples different sub-circuits together, selected frequencies can be attenuated. Since the resonators can be stacked along with the transformer, the impact on area can be minimized.

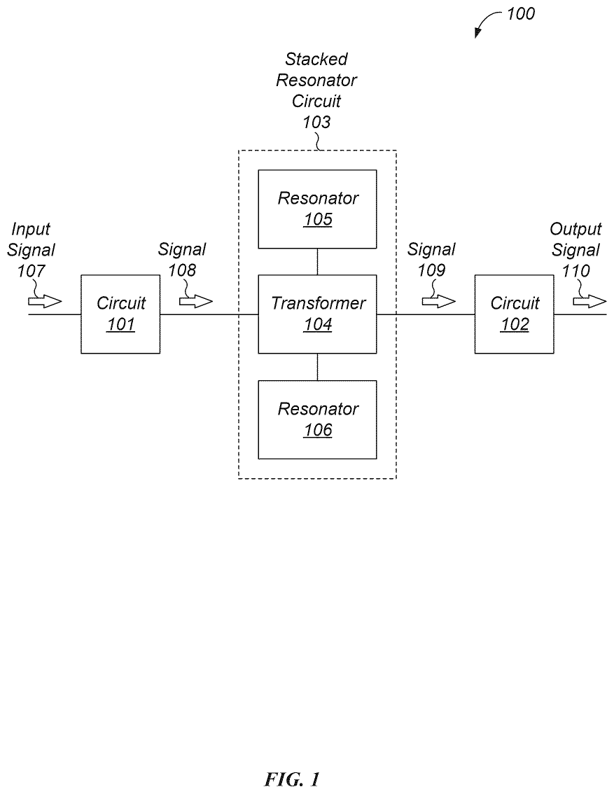

A block diagram of an embodiment of a radio-frequency circuit is depicted in FIG. 1. As illustrated, radio-frequency circuit 100 includes circuit 101, circuit 102, and stacked resonator circuit 103 (also referred to as a transformer with stacked resonators).

Circuit 101 is configured to receive input signal 107 and generate signal 108. In various embodiments, input signal 107 may be a radio-frequency signal and signal 108 may be an intermediate-frequency signal that has a lower frequency than input signal 107. In some embodiments, circuit 101 may include a mixer circuit configured to generate signal 108 by mixing input signal 107 with an intermediate-frequency signal (not shown). In various embodiments, input signal 107 may be a differential signal while, in other embodiments, input signal 107 may be a single-ended signal.

Stacked resonator circuit 103 is configured to receive signal 108 and attenuate at least one frequency component of a plurality of frequency components included in signal 108 to generate signal 109. As illustrated, stacked resonator circuit 103 includes transformer 104, resonator 105, and resonator 106.

In various embodiments, resonator 105 is configured to attenuate a first frequency component of the plurality of frequency components included in signal 108. In a similar fashion, resonator 106 is configured to attenuate a second frequency component of the plurality of frequency components included in signal 108. In some embodiments, respective frequencies of the first and second frequency components may be substantially the same while, in other embodiments, the respective frequencies may be different. In cases, where the respective frequencies are different, the respective frequencies may be selected to implement a notch filter operation on signal 108. In some embodiments, the respective frequencies are selected to filter common-mode spurs that can be introduce into signal 108 by circuit 101.

As described below, both resonator 105 and resonator 106 include inductors and capacitors configured to resonant at the frequencies of interest. The respective inductors in resonators 105 and 106 may, in various embodiments, be magnetically coupled to primary and secondary coils in transformer 104. As the primary coil in transformer 104 generates a magnetic field in response to signal 108, respective portions of the magnetic field induce resonance in resonators 105 and 106, reducing the strength of those portions of the magnetic field corresponding to the resonance frequencies. The reduce magnetic field strength corresponding to the resonant frequencies induce smaller currents in the secondary of transformer 104, thereby attenuating those frequencies to generate signal 109 which is a filtered version of signal 108.

Circuit 102 is configured to receive signal 109 and generate output signal 110 using signal 109. In some embodiments, circuit 102 may include a power detection circuit configured to generate an indication of a power level associated with input signal 107.

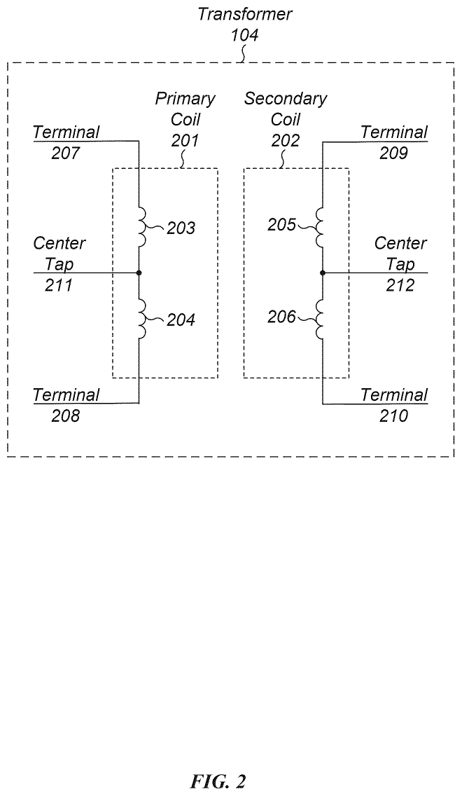

Turning to FIG. 2, a block diagram of transformer 104 is depicted. As illustrated, transformer 104 includes primary coil 201 and secondary coil 202. In various embodiments, a number of turns (or windings) of primary coil 201 may be different than a number of turns of secondary coil 202. It is noted, that, in some embodiment, a core of ferrous material may be included between primary coil 201 and secondary coil 202.

Primary coil 201 includes center tap 211, and secondary coil 202 includes center tap 212. Center tap 211 and center tap 212 may be located at substantially the respective midpoints of primary coil 201 and secondary coil 202. In various embodiments, center taps 211 and 212 may be employed to connect to other circuits, e.g., resonator 106, virtual ground circuit nodes, or may be left electrically floating.

Primary coil is coupled between terminals 207 and 208, while secondary coil 202 is coupled between terminals 209 and 210. In various embodiments, a changing current is allowed to flow between terminals 207 and 208, causing a varying magnetic field around primary coil 201. The varying magnetic field, in turn, induces a changing current in secondary coil 202 that flows between terminals 209 and 210.

In various embodiments, primary coil 201 and secondary coil 202 may be implemented using concentric rings of metal, e.g., aluminum. In such cases, both primary coil 201 and secondary coil 202 may be fabricated on a common integrated circuit. It is contemplated, however, that, in some embodiments, primary coil 201 and secondary coil 202 may be implemented as standalone discrete coils of wire or other suitable conductive material.

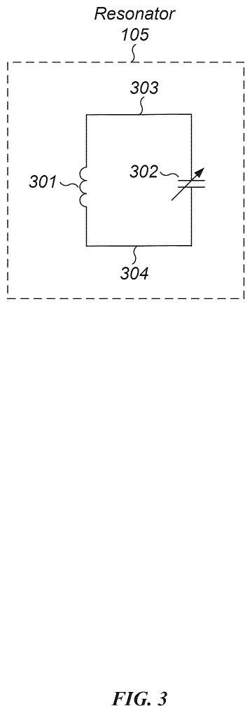

Turning to FIG. 3, a block diagram of resonator 105 is depicted. As illustrated, resonator 105 includes inductor 301 and variable capacitor 302. In various embodiments, inductor 301 is magnetically coupled to primary coil 201 and secondary coil 202. It is noted that, in some embodiments, inductor 301 and variable capacitor 302 are electrically isolated from primary coil 201 and secondary coil 202.

In various embodiments, respective component values for inductor 301 and variable capacitor 302 are selected so that resonator 105 resonates and a frequency to be attenuated in signal 108. That is, the component values of inductor 301 and variable capacitor 302 are selected such that their respective reactance values are have the same magnitude such that resonator 105 resonates at the desired frequency.

In various embodiments, inductor 301 may be implemented using one or more metal layers available in a semiconductor manufacturing process. Although depicted as a single inductor, in some embodiments, inductor 301 may be implemented using multiple inductors coupled together in any suitable series and/or parallel arrangement.

Variable capacitor 302 may be implemented using a metal-oxide-metal (MOM) capacitor structure, a metal-insulator-metal (MIM) capacitor structure, or any other suitable capacitor structure available in a semiconductor manufacturing process. Although variable capacitor 302 is depicted as a single device, in other embodiments, variable capacitor 302 may be implemented using any suitable arrangement of multiple capacitors. In some embodiments, metal switches may be employed to connect different ones of the multiple capacitors into resonator 105 to allow for programmability of the value of variable capacitor 302 during manufacturing.

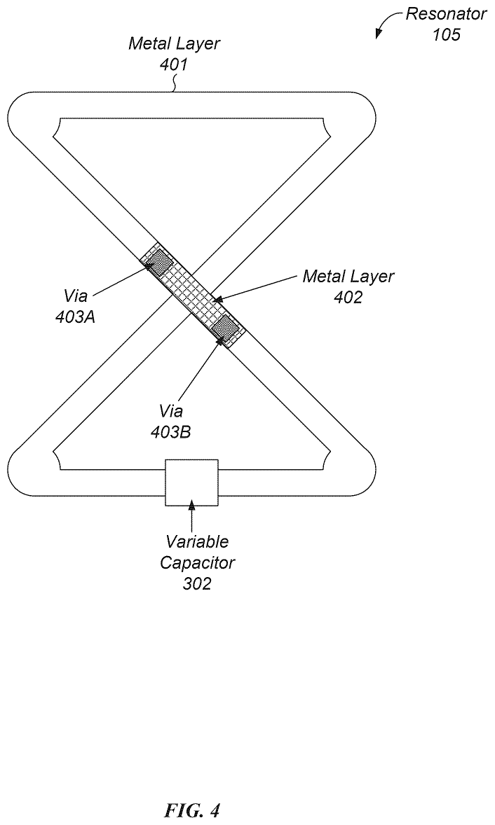

A diagram illustrating a topology of an embodiment of resonator 105 is depicted in FIG. 4. As illustrated, the general shape of resonator 105 is that of a square with a half-fold, creating a bow-tie shape. In various embodiments, the two rings formed from the half-fold generate magnetic fields in opposite directions, canceling the each other's effect in the transmission of the differential mode signals in transformer 104.

Inductor 301 is fabricated using metal layers 401 and 402, which are separated by an oxide or other insulating layer. To allow inductor 301 to be folded over itself, a jumper of metal layer 402 is employed to prevent creating a short circuit at the intersection resulting from the fold. Vias 403A and 403B are used to connect metal layer 401 to metal layer 402. Although two vias are depicted in the embodiment of FIG. 4, in other embodiments, any suitable number of vias may be employed. It is noted that metal layer 402 may be above or below metal layer 401 in the metal layers available on a semiconductor manufacturing process.

Variable capacitor 302 is coupled to a segment of inductor 301 fabricated in metal layer 401. As described above, variable capacitor 302 is connected in series with the coil formed by the structures in metal layer 401 and metal layer 402. It is noted that the location of variable capacitor 302 is merely an example and that, in other embodiments, variable capacitor 302 may be located in any suitable location within resonator 105.

The topology of depicted in FIG. 4 is merely an example of a topology that can be used to fabricate resonator 105. It is possible and contemplated that other topologies can be employed in various embodiments.

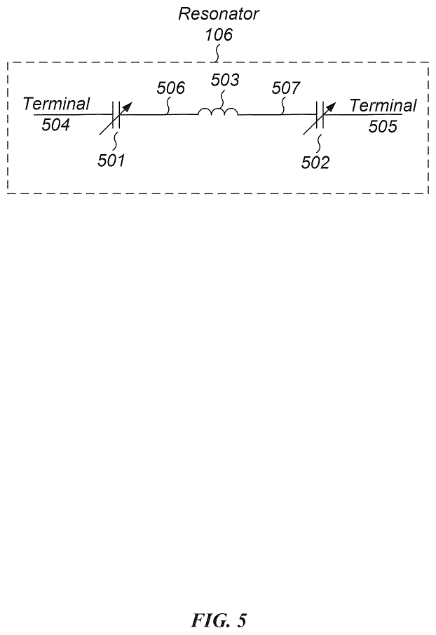

Turning to FIG. 5, a block diagram of an embodiment of resonator 106 is depicted. As illustrated, resonator 106 includes variable capacitors 501 and 502, and inductor 503. Variable capacitor 501 is coupled between terminal 504 and node 506, while variable capacitor 502 is coupled between node 507 and terminal 505. Inductor 503 is coupled between nodes 506 and 507.

In various embodiments, terminals 504 and 505 are coupled to center taps 211 and 212, respectively. In some embodiments, inductor 503 is magnetically coupled to primary coil 201 and secondary coil 202.

In various embodiments, respective component values for inductor 503 and variable capacitors 501 and 502 are selected so that resonator 106 resonates and a frequency to be attenuated in signal 108. In some embodiments, the respective component values for inductor 503 and variable capacitors 501 and 502 are selected to attenuate a different frequency than resonator 105 in order to perform a function similar to that of a notch filter.

In various embodiments, inductor 503 may be implemented using one or more metal layers available in a semiconductor manufacturing process. Although depicted as a single inductor, in some embodiments, inductor 503 may be implemented using multiple inductors coupled together in any suitable series and/or parallel arrangement.

Variable capacitors 501 and 502 may be implemented using a MOM capacitor structure, a MIM capacitor structure, or any other suitable capacitor structure available in a semiconductor manufacturing process. Although variable capacitors 501 and 502 are depicted as single devices, in other embodiments, variable capacitors 501 and 502 may be implemented using any suitable arrangement of multiple capacitors. In some embodiments, metal switches may be employed to connect different ones of the multiple capacitors into resonator 106 to allow for programmability of the values of variable capacitors 501 and 502 during manufacturing.

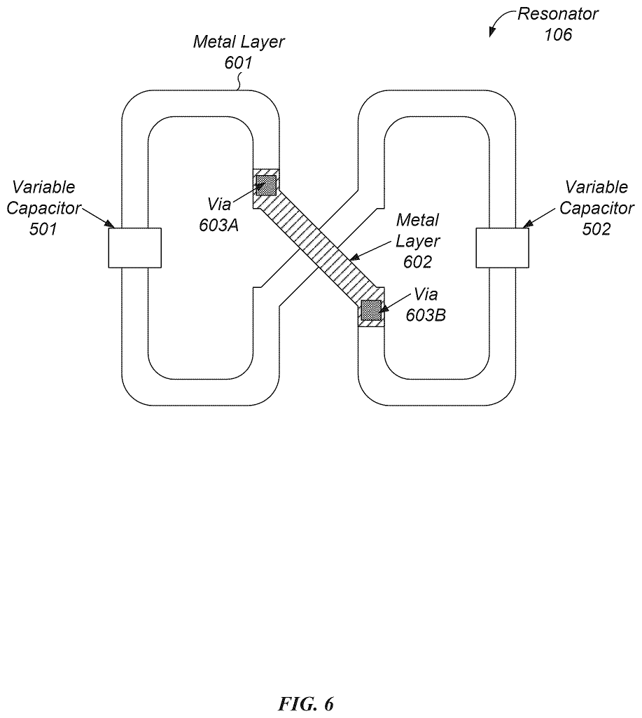

A diagram illustrating a topology of an embodiment of resonator 106 is depicted in FIG. 6. As illustrated, the general shape of resonator 106 is that of two cross-connected loops.

Inductor 503 is fabricated using metal layers 601 and 602, which are separated by an oxide or other insulating layer. The cross connection is achieved using metal layer 602 to prevent a short circuit at the cross connection. Vias 603A and 603B are used to connect metal layer 601 to metal layer 602. Although two vias are depicted in the embodiment of FIG. 6, in other embodiments, any suitable number of vias may be employed. It is noted that metal layer 602 may be above or below metal layer 601 in the metal layers available on a semiconductor manufacturing process.

Variable capacitors 501 and 502 are coupled to a respective segments of inductor 503 fabricated in metal layer 601. As described above, variable capacitors 501 and 502 are connected in series with the coil formed by the structures in metal layer 601 and metal layer 602. It is noted that the location of variable capacitors 501 and 502 are merely examples and that, in other embodiments, variable capacitors 501 and 502 may be located in any suitable location within resonator 106.

The topology of depicted in FIG. 6 is merely an example of a topology that can be used to fabricate resonator 106. It is possible and contemplated that other topologies can be employed in various embodiments.

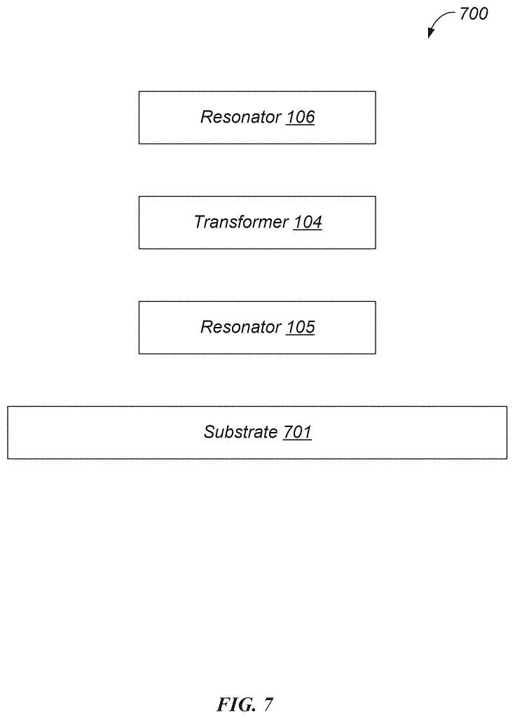

Turning to FIG. 7, a block diagram of an embodiment of a cross-section of stacked resonator circuit 103 is depicted. As described above, the inductors or coils included in transformer 104, resonator 105, and resonator 106 may be fabricated on different groups of metal layers available in a semiconductor manufacturing process. By using different groups of metal layers, transformer 104, resonator 105, and resonator 106 may be stacked vertically relative to substrate 701, minimizing the area impact of stacked resonator circuit 103.

As illustrated, each of transformer 104, resonator 105, and resonator 106 are oriented in a parallel fashion to a plane of substrate 701. In the embodiment of cross-section 700 depicted in FIG. 7, transformer 104 is located between resonator 105 and resonator 106, with resonator 105 being closer to substrate 701 that either of transformer 104 and resonator 106. In some embodiments, vias (not shown) can allow for electrical connections between transformer 104, resonator 105, and resonator 106. For example, vias may be used to connect terminals 504 and 505, to center taps 211 and 212.

Since transformer 104 is disposed between resonator 105 and resonator 106, coupling between resonators 105 and 106 is minimized, while still allowing each of resonators 105 and 106 to couple with the primary and secondary coils of transformer 104.

In some embodiments, the distances between transformer 104, resonator 105, and resonator 106 may be based on a thickness of an oxide or other insulating layer between different metal layers in a semiconductor process. In some cases, additional oxide or insulating layers may be employed to adjust the spacing between transformer 104, resonator 105, and resonator 106.

Although a single resonator is depicted above and below transformer 104, in other embodiments, any suitable number of resonators may be included both above and/or below transformer 104. In such cases, each of the resonators may be tuned to different frequencies to generate the desired transfer function from the primary to secondary side of transformer 104.

To summarize, various embodiments of a stacked resonator circuit are disclosed. Broadly speaking, a stacked coupled circuit may include a transformer and a plurality of resonator circuits coupled to the transformer. The transformer circuit, that includes a primary coil and a secondary coil, may be coupled between a first circuit and a second circuit, and may be configured to receive a first signal from the first circuit. The plurality of resonator circuits may be configured to attenuate at least one frequency component of a plurality of frequency components included in the first signal to generate a second signal. The transformer may be further configured to relay the second signal to the second circuit.

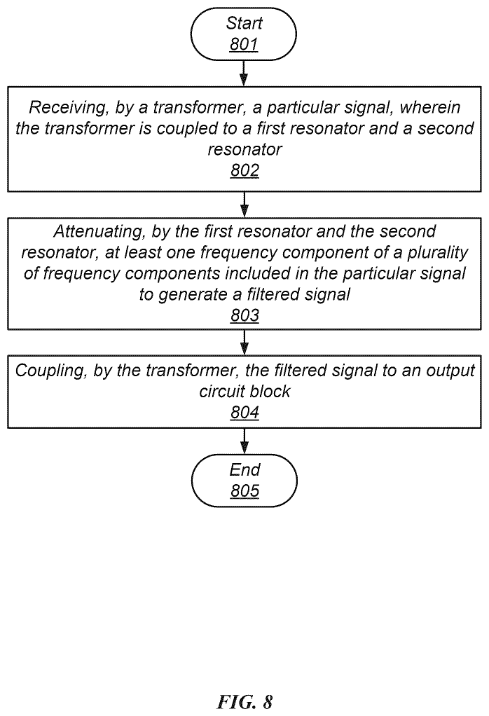

Turning to FIG. 8, a flow diagram depicting an embodiment of a method for operating a transformer with associated resonators is illustrated. The method, which may be applied to various stacked resonator circuits, e.g., stacked resonator circuit 103 as depicted in FIG. 1, begins in block 801.

The method includes receiving, by a transformer, a particular signal (block 802). In various embodiments, the transformer includes a primary coil and a secondary coil. In some embodiments, the primary coil is coupled to an input circuit, and the secondary coil is coupled to an output circuit. In other embodiments, the particular signal may comprise a differential signal.

The method also includes attenuating, by the first resonator and the second resonator, at least one frequency component of a plurality of frequency components included in the particular signal to generate a filtered signal (block 803). In cases where the particular signal comprises a differential signal, the at least one frequency component may correspond to a common-mode frequency of the differential signal.

In some embodiments, the first resonator may include a variable capacitor and an inductor coupled in series. The inductor may, in different embodiments, be magnetically coupled to the primary coil and the secondary coil of the transformer.

In various embodiments, the second resonator may include a first variable capacitor coupled to a first center tap of the primary coil of the transformer, and a second variable capacitor coupled to a second center tap of the secondary coil of the transformer. In such cases, the second resonator may include another inductor coupled between the first variable capacitor and the second variable capacitor. In some embodiments, the other inductor is magnetically coupled to the primary coil and the secondary coil of the transformer.

In some embodiments, attenuating the at least on frequency component may include attenuating, by the first resonator, a first frequency component of the plurality of frequency components, and attenuating, by the second resonator, a second frequency component of the plurality of frequency components. In other embodiments, a first frequency of the first frequency component may be different than a second frequency of the second frequency component.

The method further includes coupling, by the transformer, the filtered signal to an output circuit block (block 804). In cases, where the particular signal comprises a differential signal, the filtered signal may comprise a different differential signal. The method concludes in block 805.

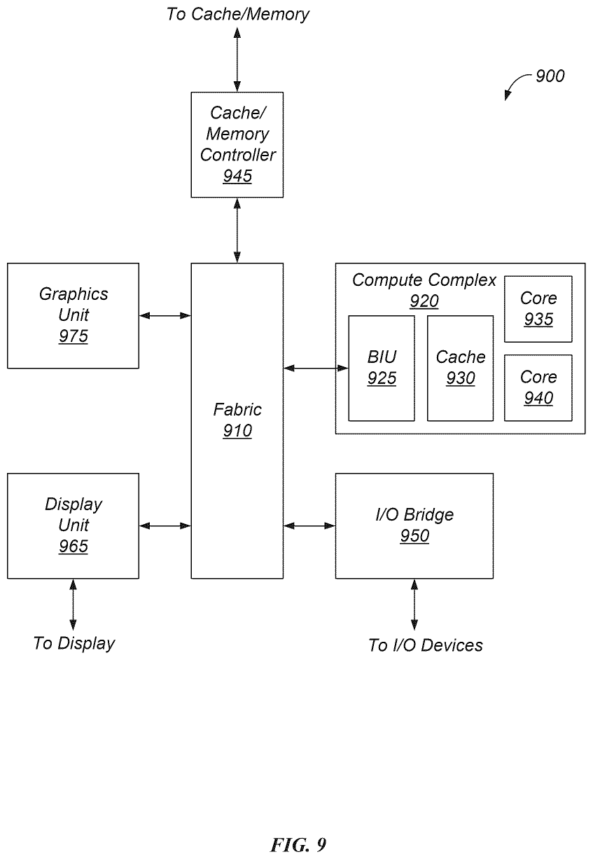

Referring now to FIG. 9, a block diagram illustrating an example embodiment of a device is shown. In some embodiments, elements of device 900 may be included within a system on a chip. In some embodiments, device 900 may be included in a mobile device, which may be battery-powered. Therefore, power consumption by device 900 may be an important design consideration. In the illustrated embodiment, device 900 includes fabric 910, compute complex 920, input/output (I/O) bridge 950, cache/memory controller 945, graphics unit 975, and display unit 965. In some embodiments, device 900 may include other components (not shown) in addition to, or in place of, the illustrated components such as video processor encoders and decoders, image processing or recognition elements, computer vision elements, etc.

Fabric 910 may include various interconnects, buses, MUX's, controllers, etc., and may be configured to facilitate communication between various elements of device 900. In some embodiments, portions of fabric 910 may be configured to implement various different communication protocols. In other embodiments, fabric 910 may implement a single communication protocol, and elements coupled to fabric 910 may convert from the single communication protocol to other communication protocols internally.

In the illustrated embodiment, compute complex 920 includes bus interface unit (BIU) 925, cache 930, and cores 935 and 940. In various embodiments, compute complex 920 may include various numbers of processors, processor cores, and caches. For example, compute complex 920 may include 1, 2, or 4 processor cores, or any other suitable number. In one embodiment, cache 930 is a set associative L2 cache. In some embodiments, cores 935 and 940 may include internal instruction and data caches. In some embodiments, a coherency unit (not shown) in fabric 910, cache 930, or elsewhere in device 900, may be configured to maintain coherency between various caches of device 900. BIU 925 may be configured to manage communication between compute complex 920 and other elements of device 900. Processor cores, such as cores 935 and 940, may be configured to execute instructions of a particular instruction set architecture (ISA) which may include operating system instructions and user application instructions. These instructions may be stored in a computer readable medium such as a memory coupled to cache/memory controller 945 as discussed below.

As used herein, the term “coupled to” may indicate one or more connections between elements, and a coupling may include intervening elements. For example, in FIG. 9, graphics unit 975 may be described as “coupled to” a memory through fabric 910 and cache/memory controller 945. In contrast, in the illustrated embodiment of FIG. 9, graphics unit 975 is “directly coupled” to fabric 910 because there are no intervening elements.

Cache/memory controller 945 may be configured to manage transfer of data between fabric 910 and one or more caches and memories. For example, cache/memory controller 945 may be coupled to an L3 cache, which may, in turn, be coupled to a system memory. In other embodiments, cache/memory controller 945 may be directly coupled to a memory. In some embodiments, cache/memory controller 945 may include one or more internal caches. Memory coupled to cache/memory controller 945 may be any type of volatile memory, such as dynamic random access memory (DRAM), synchronous DRAM (SDRAM), double data rate (DDR, DDR2, DDR3, etc.) SDRAM (including mobile versions of SDRAMs such as mDDR3, etc., and/or low power versions of SDRAMs such as LPDDR4, etc.), RAMBUS DRAM (RDRAM), static RAM (SRAM), etc. One or more memory devices may be coupled onto a circuit board to form memory modules such as single inline memory modules (SIMMs), dual inline memory modules (DIMMs), etc. Alternatively, the devices may be mounted with an integrated circuit in a chip-on-chip configuration, a package-on-package configuration, or a multi-chip module configuration. Memory coupled to cache/memory controller 945 may be any type of non-volatile memory such as NAND flash memory, NOR flash memory, nano RAM (NRAM), magneto-resistive RAM (MRAM), phase change RAM (PRAM), Racetrack memory, Memristor memory, etc. As noted above, this memory may store program instructions executable by compute complex 920 to cause the computing device to perform functionality described herein.

Graphics unit 975 may include one or more processors, e.g., one or more graphics processing units (GPUs). Graphics unit 975 may receive graphics-oriented instructions, such as OPENGL®, Metal®, or DIRECT3D® instructions, for example. Graphics unit 975 may execute specialized GPU instructions or perform other operations based on the received graphics-oriented instructions. Graphics unit 975 may generally be configured to process large blocks of data in parallel, and may build images in a frame buffer for output to a display, which may be included in the device or may be a separate device. Graphics unit 975 may include transform, lighting, triangle, and rendering engines in one or more graphics processing pipelines. Graphics unit 975 may output pixel information for display images. Graphics unit 975, in various embodiments, may include programmable shader circuitry which may include highly parallel execution cores configured to execute graphics programs, which may include pixel tasks, vertex tasks, and compute tasks (which may or may not be graphics-related).

Display unit 965 may be configured to read data from a frame buffer and provide a stream of pixel values for display. Display unit 965 may be configured as a display pipeline in some embodiments. Additionally, display unit 965 may be configured to blend multiple frames to produce an output frame. Further, display unit 965 may include one or more interfaces (e.g., MIPI® or embedded display port (eDP)) for coupling to a user display (e.g., a touchscreen or an external display).

I/O bridge 950 may include various elements configured to implement universal serial bus (USB) communications, security, audio, and low-power always-on functionality, for example. I/O bridge 950 may also include interfaces such as pulse-width modulation (PWM), general-purpose input/output (GPIO), serial peripheral interface (SPI), and inter-integrated circuit (I2C), for example. Various types of peripherals and devices, e.g., radio-frequency circuit 100, may be coupled to device 900 via I/O bridge 950.

In some embodiments, device 900 includes network interface circuitry (not explicitly shown), which may be connected to fabric 910 or I/O bridge 950. The network interface circuitry may be configured to communicate via various networks, which may be wired, wireless, or both. For example, the network interface circuitry may be configured to communicate via a wired local area network, a wireless local area network (e.g., via Wi-Fi™), or a wide area network (e.g., the Internet or a virtual private network). In some embodiments, the network interface circuitry is configured to communicate via one or more cellular networks that use one or more radio access technologies. In some embodiments, the network interface circuitry is configured to communicate using device-to-device communications (e.g., Bluetooth® or Wi-Fi™ Direct), etc. In various embodiments, the network interface circuitry may provide device 900 with connectivity to various types of other devices and networks.

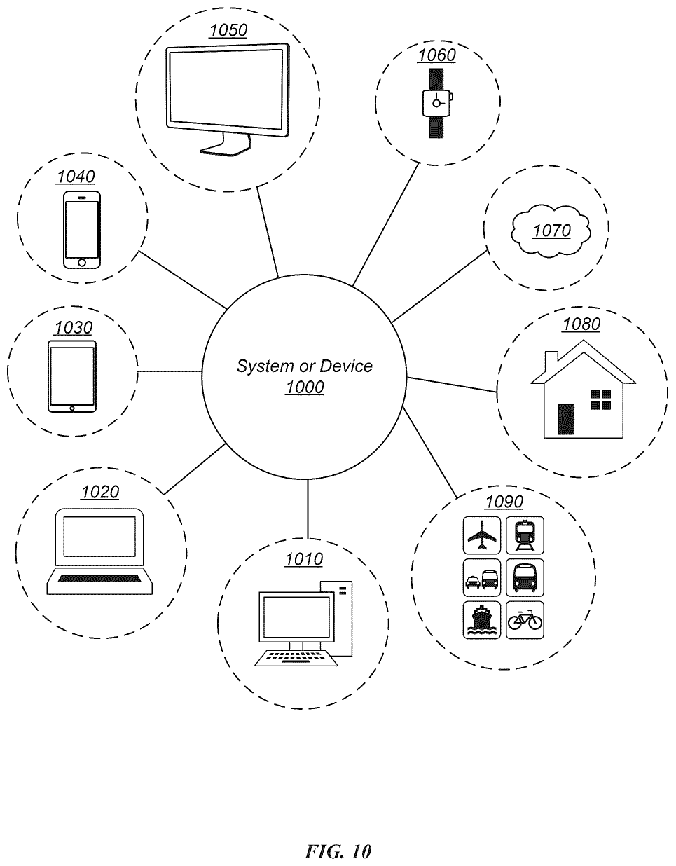

Turning now to FIG. 10, various types of systems that may include any of the circuits, devices, or systems discussed above are illustrated. System or device 1000, which may incorporate or otherwise utilize one or more of the techniques described herein, may be utilized in a wide range of areas. For example, system or device 1000 may be utilized as part of the hardware of systems such as a desktop computer 1010, laptop computer 1020, tablet computer 1030, cellular or mobile phone 1040, or television 1050 (or set-top box coupled to a television).

Similarly, disclosed elements may be utilized in a wearable device 1060, such as a smartwatch or a health-monitoring device. Smartwatches, in many embodiments, may implement a variety of different functions—for example, access to email, cellular service, calendar, health monitoring, etc. A wearable device may also be designed solely to perform health-monitoring functions, such as monitoring a user's vital signs, performing epidemiological functions such as contact tracing, providing communication to an emergency medical service, etc. Other types of devices are also contemplated, including devices worn on the neck, devices implantable in the human body, glasses or a helmet designed to provide computer-generated reality experiences such as those based on augmented and/or virtual reality, etc.

System or device 1000 may also be used in various other contexts. For example, system or device 1000 may be utilized in the context of a server computer system, such as a dedicated server or on shared hardware that implements a cloud-based service 1070. Still further, system or device 1000 may be implemented in a wide range of specialized everyday devices, including devices 1080 commonly found in the home such as refrigerators, thermostats, security cameras, etc. The interconnection of such devices is often referred to as the “Internet of Things” (IoT). Elements may also be implemented in various modes of transportation. For example, system or device 1000 could be employed in the control systems, guidance systems, entertainment systems, etc. of various types of vehicles 1090.

The applications illustrated in FIG. 10 are merely exemplary and are not intended to limit the potential future applications of disclosed systems or devices. Other example applications include, without limitation: portable gaming devices, music players, data storage devices, unmanned aerial vehicles, etc.

The present disclosure has described various example circuits in detail above. It is intended that the present disclosure cover not only embodiments that include such circuitry, but also a computer-readable storage medium that includes design information that specifies such circuitry. Accordingly, the present disclosure is intended to support claims that cover not only an apparatus that includes the disclosed circuitry, but also a storage medium that specifies the circuitry in a format that programs a computing system to generate a simulation model of the hardware circuit, programs a fabrication system configured to produce hardware (e.g., an integrated circuit) that includes the disclosed circuitry, etc. Claims to such a storage medium are intended to cover, for example, an entity that produces a circuit design, but does not itself perform complete operations such as design simulation, design synthesis, circuit fabrication, etc.

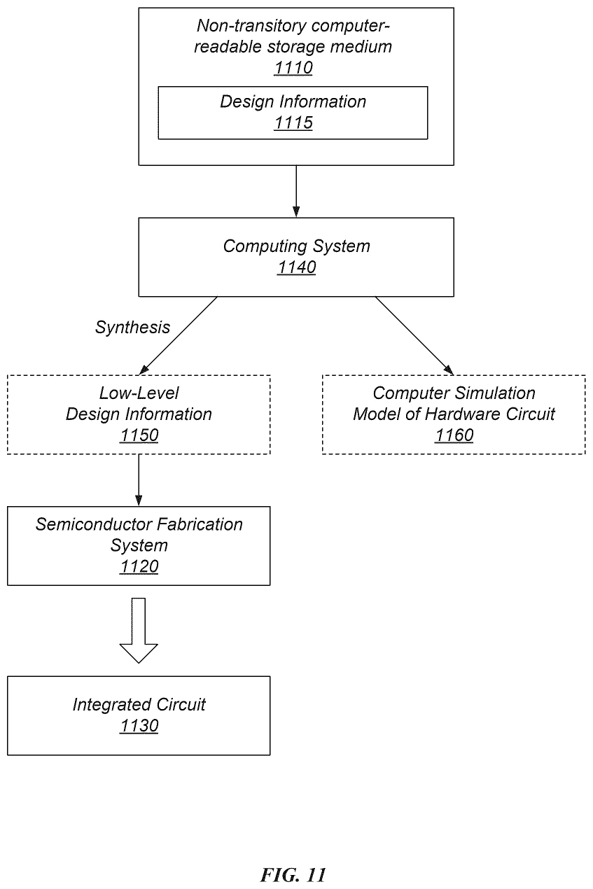

FIG. 11 is a block diagram illustrating an example of a non-transitory computer-readable storage medium that stores design information 1115, according to some embodiments. In the illustrated embodiment, computing system 1140 is configured to process design information 1115. This may include executing instructions included in design information 1115, interpreting instructions included in design information 1115, compiling, transforming, or otherwise updating design information 1115, etc. Therefore, design information 1115 controls computing system 1140 (e.g., by programming computing system 1140) to perform various operations discussed below, in some embodiments.

In the illustrated example, computing system 1140 processes design information 1115 to generate both computer simulation model of hardware circuit 1160 and low-level design information 1150. In other embodiments, computing system 1140 may generate only one of these outputs, may generate other outputs based on design information 1115, or both. Regarding computer simulation model of hardware circuit 1160, computing system 1140 may execute instructions of a hardware description language that includes register transfer level (RTL) code, behavioral code, structural code, or some combination thereof. The simulation model may perform the functionality specified by design information 1115, facilitate verification of the functional correctness of the hardware design, generate power consumption estimates, generate timing estimates, etc.

In the illustrated example, computing system 1140 also processes design information 1115 to generate low-level design information 1150 (e.g., gate-level design information, a netlist, etc.). This may include synthesis operations, as shown, such as constructing a multi-level network, optimizing the network using technology-independent techniques, technology dependent techniques, or both, and outputting a network of gates (with potential constraints based on available gates in a technology library, sizing, delay, power, etc.). Based on low-level design information 1150 (potentially among other inputs), semiconductor fabrication system 1120 is configured to fabricate integrated circuit 1130 (which may correspond to functionality of the computer simulation model of hardware circuit 1160). Note that computing system 1140 may generate different simulation models based on design information at various levels of description, including low-level design information 1150, design information 1115, and so on. The data representing low-level design information 1150 and computer simulation model of hardware circuit 1160 may be stored on non-transitory computer-readable storage medium 1110, or on one or more other media.

In some embodiments, low-level design information 1150 controls (e.g., programs) semiconductor fabrication system 1120 to fabricate integrated circuit 1130. Thus, when processed by the fabrication system, the design information may program the fabrication system to fabricate a circuit that includes various circuitry disclosed herein.

Non-transitory computer-readable storage medium 1110 may comprise any of various appropriate types of memory devices or storage devices. Non-transitory computer-readable storage medium 1110 may be an installation medium, e.g., a CD-ROM, floppy disks, or tape device; a computer system memory or random access memory such as DRAM, DDR RAM, SRAM, EDO RAM, Rambus RAM, etc.; a non-volatile memory such as a Flash memory, magnetic media, e.g., a hard drive, or optical storage; registers, or other similar types of memory elements, etc. Non-transitory computer-readable storage medium 1110 may include other types of non-transitory memory as well, or combinations thereof. Accordingly, non-transitory computer-readable storage medium 1110 may include two or more memory media, which may reside in different locations—for example, in different computer systems that are connected over a network.

Design information 1115 may be specified using any of various appropriate computer languages, including hardware description languages such as, without limitation: VHDL, Verilog, SystemC, SystemVerilog, RHDL, M, MyHDL, etc. The format of various design information may be recognized by one or more applications executed by computing system 1140, semiconductor fabrication system 1120, or both. In some embodiments, design information 1115 may also include one or more cell libraries that specify the synthesis, layout, or both of integrated circuit 1130. In some embodiments, design information 1115 is specified in whole, or in part, in the form of a netlist that specifies cell library elements and their connectivity. Design information discussed herein, taken alone, may or may not include sufficient information for fabrication of a corresponding integrated circuit. For example, design information may specify the circuit elements to be fabricated but not their physical layout. In this case, design information may be combined with layout information to actually fabricate the specified circuitry.

Integrated circuit 1130 may, in various embodiments, include one or more custom macrocells, such as memories, analog or mixed-signal circuits, and the like. In such cases, design information 1115 may include information related to included macrocells. Such information may include, without limitation, schematics capture database, mask design data, behavioral models, and device or transistor level netlists. Mask design data may be formatted according to graphic data system (GDSII), or any other suitable format.

Semiconductor fabrication system 1120 may include any of various appropriate elements configured to fabricate integrated circuits. This may include, for example, elements for depositing semiconductor materials (e.g., on a wafer, which may include masking), removing materials, altering the shape of deposited materials, modifying materials (e.g., by doping materials or modifying dielectric constants using ultraviolet processing), etc. Semiconductor fabrication system 1120 may also be configured to perform various testing of fabricated circuits for correct operation.

In various embodiments, integrated circuit 1130 and computer simulation model of hardware circuit 1160 are configured to operate according to a circuit design specified by design information 1115, which may include performing any of the functionality described herein. For example, integrated circuit 1130 may include any of various elements shown in FIG. 1-7. Further, integrated circuit 1130 may be configured to perform various functions described herein in conjunction with other components. Further, the functionality described herein may be performed by multiple connected integrated circuits.

As used herein, a phrase of the form “design information that specifies a design of a circuit configured to . . . ” does not imply that the circuit in question must be fabricated in order for the element to be met. Rather, this phrase indicates that the design information describes a circuit that, upon being fabricated, will be configured to perform the indicated actions or will include the specified components. Similarly, stating “instructions of a hardware description programming language” that are “executable” to program a computing system to generate a computer simulation model does not imply that the instructions must be executed in order for the element to be met, but rather, specifies characteristics of the instructions. Additional features relating to the model (or the circuit represented by the model) may similarly relate to characteristics of the instructions, in this context. Therefore, an entity that sells a computer-readable medium with instructions that satisfy recited characteristics may provide an infringing product, even if another entity actually executes the instructions on the medium.

Note that a given design, at least in the digital logic context, may be implemented using a multitude of different gate arrangements, circuit technologies, etc. As one example, different designs may select or connect gates based on design tradeoffs (e.g., to focus on power consumption, performance, circuit area, etc.). Further, different manufacturers may have proprietary libraries, gate designs, physical gate implementations, etc. Different entities may also use different tools to process design information at various layers (e.g., from behavioral specifications to physical layout of gates).

Once a digital logic design is specified, however, those skilled in the art need not perform substantial experimentation or research to determine those implementations. Rather, those of skill in the art understand procedures to reliably and predictably produce one or more circuit implementations that provide the function described by design information 1115. The different circuit implementations may affect the performance, area, power consumption, etc. of a given design (potentially with tradeoffs between different design goals), but the logical function does not vary among the different circuit implementations of the same circuit design.

In some embodiments, the instructions included in design information 1115 provide RTL information (or other higher-level design information) and are executable by the computing system to synthesize a gate-level netlist that represents the hardware circuit based on the RTL information as an input. Similarly, the instructions may provide behavioral information and be executable by the computing system to synthesize a netlist or other lower-level design information included in low-level design information 1150. Low-level design information 1150 may program semiconductor fabrication system 1120 to fabricate integrated circuit 1130.

The present disclosure includes references to an “embodiment” or groups of “embodiments” (e.g., “some embodiments” or “various embodiments”). Embodiments are different implementations or instances of the disclosed concepts. References to “an embodiment,” “one embodiment,” “a particular embodiment,” and the like do not necessarily refer to the same embodiment. A large number of possible embodiments are contemplated, including those specifically disclosed, as well as modifications or alternatives that fall within the spirit or scope of the disclosure.

This disclosure may discuss potential advantages that may arise from the disclosed embodiments. Not all implementations of these embodiments will necessarily manifest any or all of the potential advantages. Whether an advantage is realized for a particular implementation depends on many factors, some of which are outside the scope of this disclosure. In fact, there are a number of reasons why an implementation that falls within the scope of the claims might not exhibit some or all of any disclosed advantages. For example, a particular implementation might include other circuitry outside the scope of the disclosure that, in conjunction with one of the disclosed embodiments, negates or diminishes one or more of the disclosed advantages. Furthermore, suboptimal design execution of a particular implementation (e.g., implementation techniques or tools) could also negate or diminish disclosed advantages. Even assuming a skilled implementation, realization of advantages may still depend upon other factors such as the environmental circumstances in which the implementation is deployed. For example, inputs supplied to a particular implementation may prevent one or more problems addressed in this disclosure from arising on a particular occasion, with the result that the benefit of its solution may not be realized. Given the existence of possible factors external to this disclosure, it is expressly intended that any potential advantages described herein are not to be construed as claim limitations that must be met to demonstrate infringement. Rather, identification of such potential advantages is intended to illustrate the type(s) of improvement available to designers having the benefit of this disclosure. That such advantages are described permissively (e.g., stating that a particular advantage “may arise”) is not intended to convey doubt about whether such advantages can in fact be realized, but rather to recognize the technical reality that realization of such advantages often depends on additional factors.

Unless stated otherwise, embodiments are non-limiting. That is, the disclosed embodiments are not intended to limit the scope of claims that are drafted based on this disclosure, even where only a single example is described with respect to a particular feature. The disclosed embodiments are intended to be illustrative rather than restrictive, absent any statements in the disclosure to the contrary. The application is thus intended to permit claims covering disclosed embodiments, as well as such alternatives, modifications, and equivalents that would be apparent to a person skilled in the art having the benefit of this disclosure.

For example, features in this application may be combined in any suitable manner. Accordingly, new claims may be formulated during prosecution of this application (or an application claiming priority thereto) to any such combination of features. In particular, with reference to the appended claims, features from dependent claims may be combined with those of other dependent claims where appropriate, including claims that depend from other independent claims. Similarly, features from respective independent claims may be combined where appropriate.

Accordingly, while the appended dependent claims may be drafted such that each depends on a single other claim, additional dependencies are also contemplated. Any combinations of features in the dependent claims that are consistent with this disclosure are contemplated and may be claimed in this or another application. In short, combinations are not limited to those specifically enumerated in the appended claims.

Where appropriate, it is also contemplated that claims drafted in one format or statutory type (e.g., apparatus) are intended to support corresponding claims of another format or statutory type (e.g., method).

Because this disclosure is a legal document, various terms and phrases may be subject to administrative and judicial interpretation. Public notice is hereby given that the following paragraphs, as well as definitions provided throughout the disclosure, are to be used in determining how to interpret claims that are drafted based on this disclosure.

References to a singular form of an item (i.e., a noun or noun phrase preceded by “a,” “an,” or “the”) are, unless context clearly dictates otherwise, intended to mean “one or more.” Reference to “an item” in a claim thus does not, without accompanying context, preclude additional instances of the item. A “plurality” of items refers to a set of two or more of the items.

The word “may” is used herein in a permissive sense (i.e., having the potential to, being able to) and not in a mandatory sense (i.e., must).

The terms “comprising” and “including,” and forms thereof, are open-ended and mean “including, but not limited to.”

When the term “or” is used in this disclosure with respect to a list of options, it will generally be understood to be used in the inclusive sense unless the context provides otherwise. Thus, a recitation of “x or y” is equivalent to “x or y, or both,” and thus covers 1) x but not y, 2) y but not x, and 3) both x and y. On the other hand, a phrase such as “either x or y, but not both” makes clear that “or”is being used in the exclusive sense.

A recitation of “w, x, y, or z, or any combination thereof” or “at least one of . . . w, x, y, and z” is intended to cover all possibilities involving a single element up to the total number of elements in the set. For example, given the set [w, x, y, z], these phrasings cover any single element of the set (e.g., w but not x, y, or z), any two elements (e.g., w and x, but not y or z), any three elements (e.g., w, x, and y, but not z), and all four elements. The phrase “at least one of . . . w, x, y, and z” thus refers to at least one element of the set [w, x, y, z], thereby covering all possible combinations in this list of elements. This phrase is not to be interpreted to require that there is at least one instance of w, at least one instance of x, at least one instance of y, and at least one instance of z.

Various “labels” may precede nouns or noun phrases in this disclosure. Unless context provides otherwise, different labels used for a feature (e.g., “first circuit,” “second circuit,” “particular circuit,” “given circuit,” etc.) refer to different instances of the feature. Additionally, the labels “first,” “second,” and “third,” when applied to a feature, do not imply any type of ordering (e.g., spatial, temporal, logical, etc.), unless stated otherwise.

The phrase “based on” is used to describe one or more factors that affect a determination. This term does not foreclose the possibility that additional factors may affect the determination. That is, a determination may be solely based on specified factors, or based on the specified factors as well as other, unspecified factors. Consider the phrase “determine A based on B. ” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on. ”

The phrases “in response to” and “responsive to” describe one or more factors that trigger an effect. This phrase does not foreclose the possibility that additional factors may affect or otherwise trigger the effect, either jointly with the specified factors or independent from the specified factors. That is, an effect may be solely in response to those factors, or may be in response to the specified factors as well as other, unspecified factors. Consider the phrase “perform A in response to B.” This phrase specifies that B is a factor that triggers the performance of A, or that triggers a particular result for A. This phrase does not foreclose that performing A may also be in response to some other factor, such as C. This phrase also does not foreclose that performing A may be jointly in response to B and C. This phrase is also intended to cover an embodiment in which A is performed solely in response to B. As used herein, the phrase “responsive to” is synonymous with the phrase “responsive at least in part to.” Similarly, the phrase “in response to” is synonymous with the phrase “at least in part in response to.”

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical). More specifically, this formulation is used to indicate that this structure is arranged to perform the one or more tasks during operation. A structure can be said to be “configured to” perform some task even if the structure is not currently being operated. Thus, an entity described or recited as being “configured to” perform some task refers to something physical, such as a device, a circuit, or a system having a processor unit and a memory storing program instructions executable to implement the task, etc. This phrase is not used herein to refer to something intangible.

In some cases, various units/circuits/components may be described herein as performing a set of tasks or operations. It is understood that those entities are “configured to” perform those tasks/operations, even if not specifically noted.

The term “configured to” is not intended to mean “configurable to.” An unprogrammed FPGA, for example, would not be considered to be “configured to” perform a particular function. This unprogrammed FPGA may be “configurable to” perform that function, however. After appropriate programming, the FPGA may then be said to be “configured to” perform the particular function.

For purposes of United States patent applications based on this disclosure, reciting in a claim that a structure is “configured to” perform one or more tasks is expressly intended not to invoke 35 U.S. C. § 112(f) for that claim element. Should Applicant wish to invoke Section 112(f) during prosecution of a United States patent application based on this disclosure, it will recite claim elements using the “means for”[performing a function] construct.

Different “circuits” may be described in this disclosure. These circuits or “circuitry” constitute hardware that includes various types of circuit elements, such as combinatorial logic, clocked storage devices (e.g., flip-flops, registers, latches, etc.), finite state machines, memory (e.g., random-access memory, embedded dynamic random-access memory), programmable logic arrays, and so on. Circuitry may be custom designed, or taken from standard libraries. In various implementations, circuitry can, as appropriate, include digital components, analog components, or a combination of both. Certain types of circuits may be commonly referred to as “units” (e.g., a decode unit, an arithmetic logic unit (ALU), a functional unit, a memory management unit (MMU), etc.). Such units also refer to circuits or circuitry.

The disclosed circuits/units/components and other elements illustrated in the drawings and described herein thus include hardware elements such as those described in the preceding paragraph. In many instances, the internal arrangement of hardware elements within a particular circuit may be specified by describing the function of that circuit. For example, a particular “decode unit” may be described as performing the function of “processing an opcode of an instruction and routing that instruction to one or more of a plurality of functional units,” which means that the decode unit is “configured to” perform this function. This specification of function is sufficient, to those skilled in the computer arts, to connote a set of possible structures for the circuit.

In various embodiments, as discussed in the preceding paragraph, circuits, units, and other elements may be defined by the functions or operations that they are configured to implement. The arrangement of such circuits/units/components with respect to each other and the manner in which they interact form a microarchitectural definition of the hardware that is ultimately manufactured in an integrated circuit or programmed into an FPGA to form a physical implementation of the microarchitectural definition. Thus, the microarchitectural definition is recognized by those of skill in the art as a structure from which many physical implementations may be derived, all of which fall into the broader structure described by the microarchitectural definition. That is, a skilled artisan presented with the microarchitectural definition supplied in accordance with this disclosure may, without undue experimentation and with the application of ordinary skill, implement the structure by coding the description of the circuits/units/components in a hardware description language (HDL) such as Verilog or VHDL. The HDL description is often expressed in a fashion that may appear to be functional. But to those of skill in the art in this field, this HDL description is the manner that is used to transform the structure of a circuit, unit, or component to the next level of implementational detail. Such an HDL description may take the form of behavioral code (which is typically not synthesizable), register transfer language (RTL) code (which, in contrast to behavioral code, is typically synthesizable), or structural code (e.g., a netlist specifying logic gates and their connectivity). The HDL description may subsequently be synthesized against a library of cells designed for a given integrated circuit fabrication technology, and may be modified for timing, power, and other reasons to result in a final design database that is transmitted to a foundry to generate masks and ultimately produce the integrated circuit. Some hardware circuits, or portions thereof, may also be custom-designed in a schematic editor and captured into the integrated circuit design along with synthesized circuitry. The integrated circuits may include transistors and other circuit elements (e.g., passive elements such as capacitors, resistors, inductors, etc.) and interconnect between the transistors and circuit elements. Some embodiments may implement multiple integrated circuits coupled together to implement the hardware circuits, and/or discrete elements may be used in some embodiments. Alternatively, the HDL design may be synthesized to a programmable logic array such as a field programmable gate array (FPGA) and may be implemented in the FPGA. This decoupling between the design of a group of circuits and the subsequent low-level implementation of these circuits commonly results in the scenario in which the circuit or logic designer never specifies a particular set of structures for the low-level implementation beyond a description of what the circuit is configured to do, as this process is performed at a different stage of the circuit implementation process.

The fact that many different low-level combinations of circuit elements may be used to implement the same specification of a circuit results in a large number of equivalent structures for that circuit. As noted, these low-level circuit implementations may vary according to changes in the fabrication technology, the foundry selected to manufacture the integrated circuit, the library of cells provided for a particular project, etc. In many cases, the choices made by different design tools or methodologies to produce these different implementations may be arbitrary.

Moreover, it is common for a single implementation of a particular functional specification of a circuit to include, for a given embodiment, a large number of devices (e.g., millions of transistors). Accordingly, the sheer volume of this information makes it impractical to provide a full recitation of the low-level structure used to implement a single embodiment, let alone the vast array of equivalent possible implementations. For this reason, the present disclosure describes structure of circuits using the functional shorthand commonly employed in the industry.

What is claimed is:

1. An apparatus, comprising:
a transformer coupled between a first circuit and a second circuit, wherein the transformer is configured to receive a first signal from the first circuit, wherein the transformer includes a primary coil and a secondary coil; and
a plurality of resonator circuits coupled to the transformer, wherein the plurality of resonator circuits configured to attenuate at least one frequency component of a plurality of frequency components included in the first signal to generate a second signal; and
wherein the transformer is further configured to relay the second signal to the second circuit.

2. The apparatus of claim 1, wherein the plurality of resonator circuits includes:
a first resonator circuit configured to attenuate a first frequency component of the plurality of frequency components included in the first signal; and
a second resonator circuit configured to attenuate a second frequency component of the plurality of frequency components included in the first signal.

3. The apparatus of claim 2, wherein the first resonator circuit includes a particular variable capacitor and a first inductor coupled in series.

4. The apparatus of claim 2, wherein the second resonator circuit includes:
a first variable capacitor coupled to a first center tap of the primary coil;
a second variable capacitor coupled to a second center tap of the secondary coil; and
a second inductor coupled between the first variable capacitor and the second variable capacitor.

5. The apparatus of claim 1, wherein the first signal comprises a differential signal.

6. The apparatus of claim 5, wherein the at least one frequency component corresponds to a common-mode frequency component of the differential signal.

7. A method, comprising:
receiving, by a transformer, a particular signal, wherein the transformer is coupled to a first resonator and a second resonator, and wherein the transformer includes a primary coil and a secondary coil;
attenuating, by the first resonator and the second resonator, at least one frequency component of a plurality of frequency components included in the particular signal to generate a filtered signal; and
coupling, by the transformer, the filtered signal to an output circuit block.

8. The method of claim 7, wherein the first resonator includes a variable capacitor and an inductor coupled in series.

9. The method of claim 7, wherein the second resonator includes:
a first variable capacitor coupled to a first center tap of the primary coil;
a second variable capacitor coupled to a second center tap of the secondary coil; and
an inductor coupled between the first variable capacitor and the second variable capacitor.

10. The method of claim 7, wherein attenuating, the at least one frequency component of the plurality of frequency components includes:
attenuating, by the first resonator, a first frequency component of the plurality of frequency components; and
attenuating, by the second resonator, a second frequency component of the plurality of frequency components.

11. The method of claim 7, further comprising, detecting, by a power detector circuit, a power level associated with the filtered signal.

12. The method of claim 7, wherein the particular signal comprises a differential signal.

13. The method of claim 12, wherein the at least one frequency component corresponds to a common-mode frequency component of the differential signal.

14. An apparatus, comprising:
a first circuit configured to:
receive an input signal; and
generate a first intermediate signal using the input signal;
a coupling circuit configured to attenuate at least one frequency component of a plurality of frequency components included in the first intermediate signal to generate a second intermediate signal, wherein the coupling circuit includes a transformer and a plurality of resonator circuits; and
a second circuit configured to:
receive the second intermediate signal; and
generate an output signal using the second intermediate signal.

15. The apparatus of claim 14, wherein the transformer includes a primary coil and a secondary coil, and wherein the plurality of resonator circuits includes:
a first resonator circuit configured to attenuate a first frequency component of the plurality of frequency components included in the first intermediate signal; and
a second resonator circuit configured to attenuate a second frequency component of the plurality of frequency components included in the first intermediate signal.

16. The apparatus of claim 15, wherein a first frequency of the first frequency component is different than a second frequency of the second frequency component.

17. The apparatus of claim 15, wherein the first resonator circuit includes a variable capacitor and an inductor coupled in series.

18. The apparatus of claim 15, wherein the second resonator circuit includes:
a first variable capacitor coupled to a first center tap of the primary coil;
a second variable capacitor coupled to a second center tap of the secondary coil; and
an inductor coupled between the first variable capacitor and the second variable capacitor.

19. The apparatus of claim 14, wherein the first circuit includes a radio-frequency mixer circuit configured to generate the first intermediate signal using the input signal and an intermediate frequency signal.

20. The apparatus of claim 14, wherein the second circuit includes a power detector circuit.
